(19) United States
(12) Patent Application Publication
(10) Pub. No.: US 2014/0366931 A1
(43) Pub. Date: Dec. 18, 2014

(54) BRACKET AND PHOTOVOLTAIC APPARATUS HAVING THE SAME

(71) Applicant: AU OPTRONICS CORP., Hsin-Chu (TW)

(72) Inventors: Sih-Siou CHIU, HSIN-CHU (TW); Min-Chien KUO, HSIN-CHU (TW)

(21) Appl. No.: 14/307,894

(22) Filed: Jun. 18, 2014

(30) Foreign Application Priority Data
Jun. 18, 2013 (CN) 201310241366.3

(51) Int. Cl. H01L 31/042; F16M 13/02; H01L 31/048

(52) U.S. Cl. CPC H01L 31/0422; H01L 31/0485; F16M 13/02
USPC 136/251; 248/205.1

(57) ABSTRACT

A Photovoltaic apparatus includes a photovoltaic panel, a frame, a bracket and a T-shaped electrical junction. The frame is defined with a receiving space therein. The photovoltaic panel is disposed in the receiving space. The bracket couples on the frame, and the bracket includes a connection portion and a hanging portion. The T-shaped electrical junction is electrically connected to the photovoltaic panel and two external devices. The connection portion fixes the bracket on the frame, and the hanging portion supports the T-shaped electrical junction.

### RELATED APPLICATIONS

This application claims priority to Chinese Application Serial Number 201310241366.3, filed Jun. 18, 2013, which is herein incorporated by reference.

### BACKGROUND

1. Field of Disclosure

The present invention relates to a bracket. More particularly, the present invention relates to a photovoltaic apparatus with a bracket.

2. Description of Related Art

As petroleum reserves decrease year by year, energy crisis has become a focus by the world in recent years, and thus alternative energy sources development is urgently needed. Among many alternative energy sources, solar energy has an advantage of inexhaustibility, and thus has been always a focal point of attention.

Conventional methods for collecting solar energy generally mount a photovoltaic apparatus on a building rooftop such that photovoltaic panels of the photovoltaic apparatus may be irradiated by sunlight for a long time so as to collect enough solar energy, and then the solar energy is further transformed to electrical current. The photovoltaic panels are electrically connected to one another via an electrical junction, and the electrical energy is further collected in an electrical storage device.

However, there is no suitable method for placing the aforementioned electrical junction, and thus the electrical junction cannot be attached to the photovoltaic apparatus as expected, thus inevitably causing more assembling inconvenience and time.

### SUMMARY

In view of this, an object of the present invention is to provide a bracket and a photovoltaic apparatus with the bracket.

In order to achieve the aforementioned object, according to an embodiment, a photovoltaic apparatus includes a frame, a photovoltaic panel, a T-shaped electrical junction and a bracket. The frame has an accommodating space. The photovoltaic panel is disposed in the accommodating space. The T-shaped electrical junction electrically connects the photovoltaic panel to two external devices. The bracket includes a connection portion and at least one hanging portion, wherein the connection portion is in a slab shape connected to the hanging portion and fixes the bracket on the frame, and the hanging portion supports the T-shaped electrical junction.

According to an embodiment, a bracket may support a T-shaped electrical junction of a photovoltaic apparatus, and the T-shaped electrical junction includes a horizontal portion and a vertical portion connected to each other. The bracket includes a connecting portion and at least one pair of hanging portions. The connecting portion is in a slab shape and may be fixed on a frame of the photovoltaic apparatus. These hanging portions are connected to the connecting portion, and may support the horizontal portion of the T-shaped electrical junction. There is a gap between the hanging portions for allowing the vertical portion of the T-shaped junction to pass through.

According to an embodiment, a bracket may supports a T-shaped electrical junction of a photovoltaic apparatus, and the T-shaped electrical junction includes a horizontal portion and a vertical portion connected to each other. The bracket includes a connecting portion and one single hanging portion. The connecting portion in a slab shape and may be fixed on a frame of the photovoltaic apparatus. The one single hanging portion is connected to the connecting portion and may support one of the vertical portion and the horizontal portion of the T-shaped electrical junction.

In the aforementioned embodiments, by using the bracket disposed on the photovoltaic apparatus, the T-shaped electrical junction can be hanged on or dismantled from the bracket briefly, thus not only conveniently replacing the T-shaped electrical junction, but also conveniently swapping the direction for installing the wires at the T-shaped electrical junction.

The above description is merely used for illustrating the problems to be resolved, the technical methods for resolving the problems and their efficacies, etc. The specific details of the present invention will be explained in the below embodiments and related drawings.

### BRIEF DESCRIPTION OF THE DRAWINGS

The invention may be more fully understood by reading the following detailed description of the embodiment, with reference made to the accompanying drawings as follows:

FIG. 1A is a front view of a photovoltaic array according to a first embodiment;

FIG. 1B is a back view of a photovoltaic apparatus shown in FIG. 1A;

FIG. 2A is a perspective view of detail 2A shown in FIG. 1B;

FIG. 2B is a perspective view of a T-shaped electrical junction shown in FIG. 2A;

FIG. 3A is a perspective view of a bracket shown in FIG. 2A;

FIG. 3B is a side view of the bracket shown in FIG. 3A;

FIG. 3C illustrates movement paths of a horizontal portion of the T-shaped electrical junction entering a holding space of a C-shaped hook;

FIG. 4 is a partial perspective view of a photovoltaic apparatus according to a second embodiment;

FIG. 5A is a perspective view of a bracket shown in FIG. 4;

FIG. 5B is a top view of the bracket shown in FIG. 5A;

FIG. 5C is a side view of the bracket shown in FIG. 5A;

FIG. 6 is a top view of another bracket according to the second embodiment;

FIG. 7A is a partial perspective view of a photovoltaic apparatus according to a third embodiment;

FIG. 7B is a side view of a bracket and a T-shaped electrical junction shown in FIG. 7A;

FIG. 8A is a perspective view of the bracket shown in FIG. 7A; and

FIG. 8B is a side view of the bracket shown in FIG. 8A.

### DETAILED DESCRIPTION

The following embodiments are disclosed with accompanying diagrams for detailed description. For illustration clarity, many details of practice are explained in the following descriptions. However, it should be understood that these details of practice do not intend to limit the present invention. That is, these details of practice are not necessary in parts of embodiments of the present invention. Furthermore, for simplifying the drawings, some of the conventional structures and elements are shown with schematic illustrations.

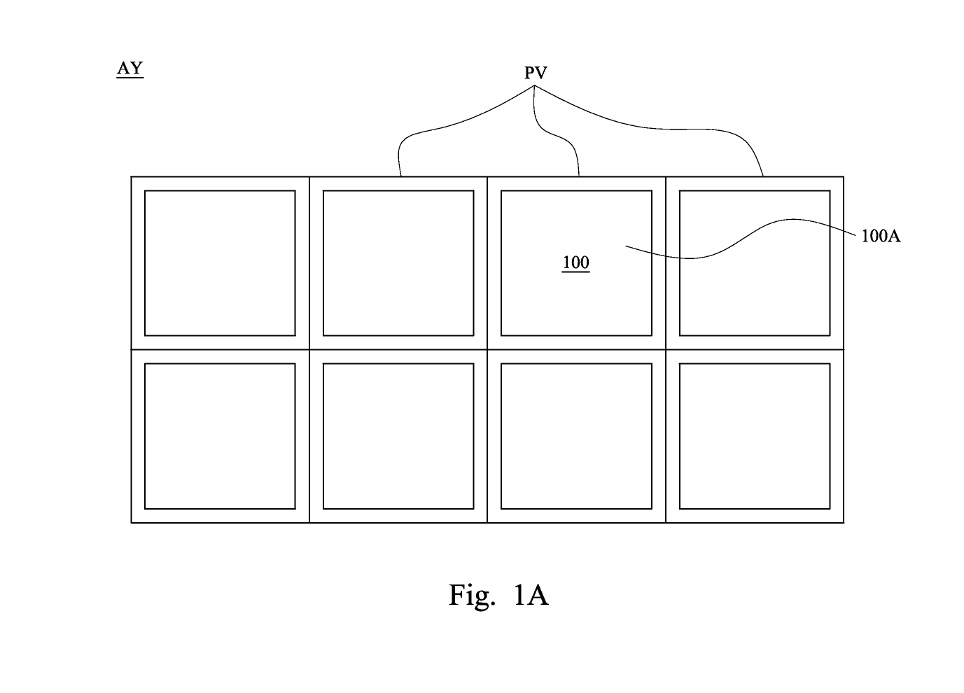

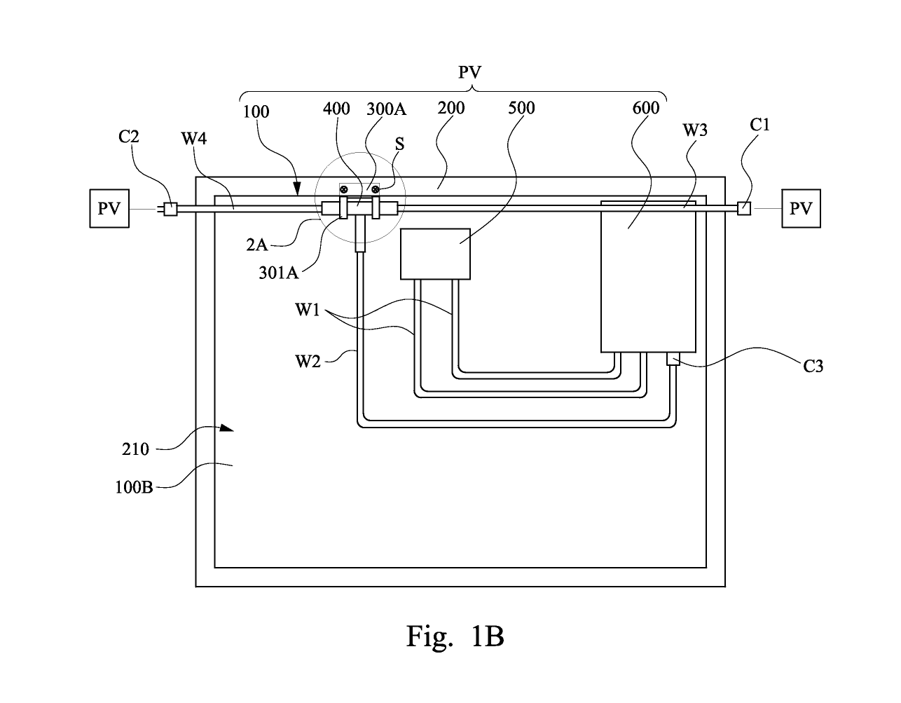

FIG. 1A is a front view of a photovoltaic array AY according to a first embodiment. FIG. 1B is a back view of a photovoltaic apparatus PV shown in FIG. 1A. Tithe photovoltaic array AY includes several photovoltaic apparatuses PV, in which the photovoltaic apparatuses PV are arranged as an array, and are electrically connected to one another by wirings (not shown). Although the photovoltaic array AY of the present embodiment includes eight photovoltaic apparatuses PV arranged in 2×4 array, but the present invention is not limited thereto.

As shown in FIGS. 1A and 1B, each photovoltaic apparatus PV includes a photovoltaic panel 100, frame 200, at least one bracket 300A and at least one T-shaped electrical junction 400. The T-shaped electrical junction 400 is electrically connected two external devices (such as two adjacent photovoltaic apparatuses PV) to the photovoltaic panel 100, and includes at least one hanging portion 301A. The T-shaped electrical junction 400 can be hanged on the hanging portion 301A without tool, such that an assembler may hang the T-shaped electrical junction on the hanging portion 301A by bare hands without using any tool. The so-called “hang” indicates that the T-shaped electrical junction 400 is held and supported by the hanging portion 301A for avoiding falling off.

Thus, the T-shaped electrical junction 400 of each photovoltaic apparatus PV may be hanged on the bracket 300A or dismantled from the bracket 300A by bare hands, such that the T-shaped electrical junction 400 can be conveniently mounted, thus reducing inconvenience for the assembler. For example, when the photovoltaic array AY is being mounted on a rooftop of a building, the assembler may rapidly install the T-shaped electrical junction 400 on the photovoltaic apparatuses PV when installing or repairing the photovoltaic apparatuses PV, thus further reducing the working time of the assembler and the risks of falling off from the building.

Besides, because the bracket 300A of the photovoltaic apparatuses PV may allow the T-shaped electrical junction 400 to be hanged on the bracket 300A by bare hands, the T-shaped electrical junction 400 may be fixed on the frame 200 without screws, such that the fastening failure due to damaged screws (such as stripped threads) will not occur. Therefore, when the direction for installing conductive wires at two opposite ends of the T-shaped electrical junction 400 has to be changed, the assembler may arbitrarily change the installing directions of the conductive wires of the T-shaped electrical junction 400 after dismantling the T-shaped electrical junction 400 from the bracket 300A, and then the assembler may hang the T-shaped electrical junction 400 rapidly on the hanging portion 301A without needing to loosen the screws first and then fastening the screws again after changing the two opposite ends of the T-shaped electrical junction 400.

Specifically, the frame 200 is rectangular or approximately rectangular, for example, and an accommodating space 210 defined in the frame 200 can receive the photovoltaic panel 100 embedded therein. The photovoltaic panel 100 includes a light-facing surface 100A (as shown in FIG. 1A) and a back surface 100B (as shown in FIG. 1B) opposite to the light-facing surface 100A. Besides, as shown in FIG. 1B, the bracket 300A is fixed at one side of the frame 200 adjacent to the back surface 100B of the photovoltaic panel 100 (as shown in FIG. 1B).

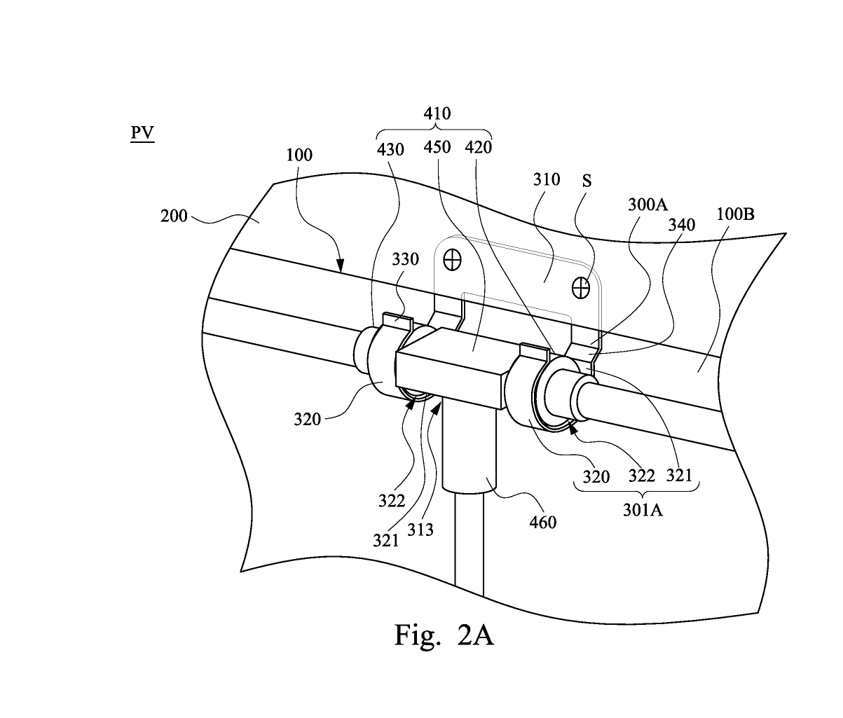

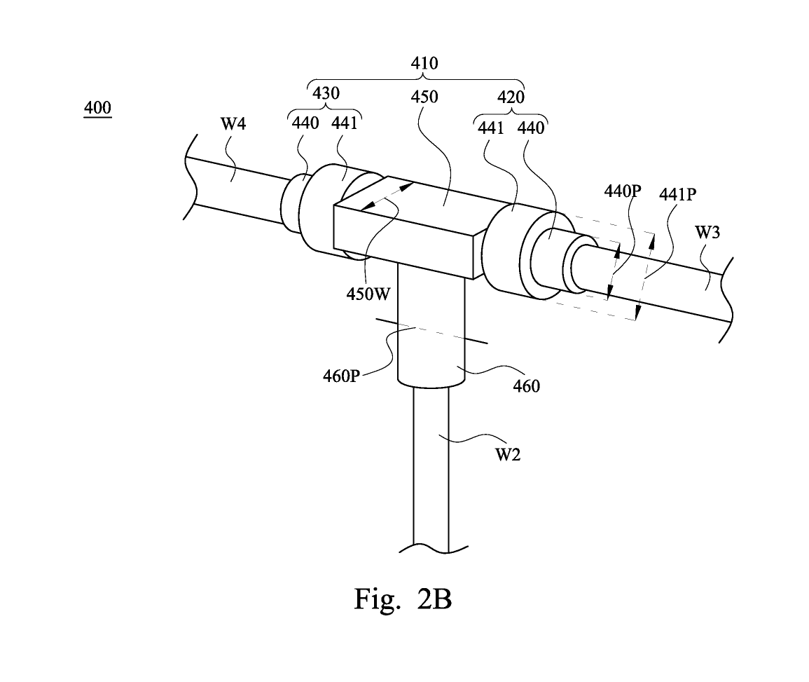

FIG. 2A is a perspective view of detail portion 2A shown in FIG. 1B. Referring to FIGS. 1B and 2A simultaneously, the bracket 300A includes a connecting portion 310 and two hanging portions 301A. The connecting portion 310 of the bracket 300A is disposed between the frame 200 and the back surface 100B, and is fixed on the frame 200 by screws S. The two hanging portions 301A are disposed at two opposite ends of the same side of the connecting portion 310.

FIG. 2B is a perspective view of T-shaped electrical junction 400 shown in FIG. 2A. As shown in FIG. 2B, the T-shaped electrical junction 400 includes a horizontal portion 410 and a vertical portion 460. The horizontal portion 460 and the vertical portion 410 are substantially extended along a straight line or an approximately straight line, and are perpendicular or at least one approximately perpendicular to each other, and thus the horizontal portion 410 combined with the vertical portion 460 forms a T-shape or a similar T-shape.

The horizontal portion 410 includes a first section 420, a second section 430 and a middle section 450 disposed between the first section 420 and the second section 430. The first section 420, the second section 430 and the middle section 450 are connected as a straight line or an approximately straight line. The middle section 450 is connected and perpendicular or approximately perpendicular to the vertical portion 460. As shown in FIG. 2B, a cross section of the middle section 450 is rectangular or approximately rectangular, and at least one metal wire (not shown) is disposed in the middle section 450 for conducting the electrical energy to an external device.

Further, as shown in FIGS. 1B and 2B, the first section 420 has a wire W3 extending along a direction away from the middle section 450, thereby electrically connecting to a previous photovoltaic apparatus PV (such as the photovoltaic apparatus at the right-hand side) via a connection C1 at the end of the wire W3. The second section 430 has a wire W4 extending along a direction away from the middle section 450, thereby electrically connecting to a next photovoltaic apparatus PV (such as the photovoltaic apparatus at the left-hand side) via a connection C2 at the end of the wire W4. The vertical portion 460 has a wire W2 extending along a direction away from the middle section 450, thereby electrically connecting to the photovoltaic panel 100 via a connection C3 at the end of the wire W2.

Therefore, after the AC current outputted from the photovoltaic panel joins the AC current from the previous photovoltaic apparatus PV using the T-shaped electrical junction 400, the jointed AC current is transmitted to the next photovoltaic apparatus PV using the wire W4 of the second section 430, such that the electrical energy of all photovoltaic apparatuses PV can be collected in an electrical storage device (not shown).

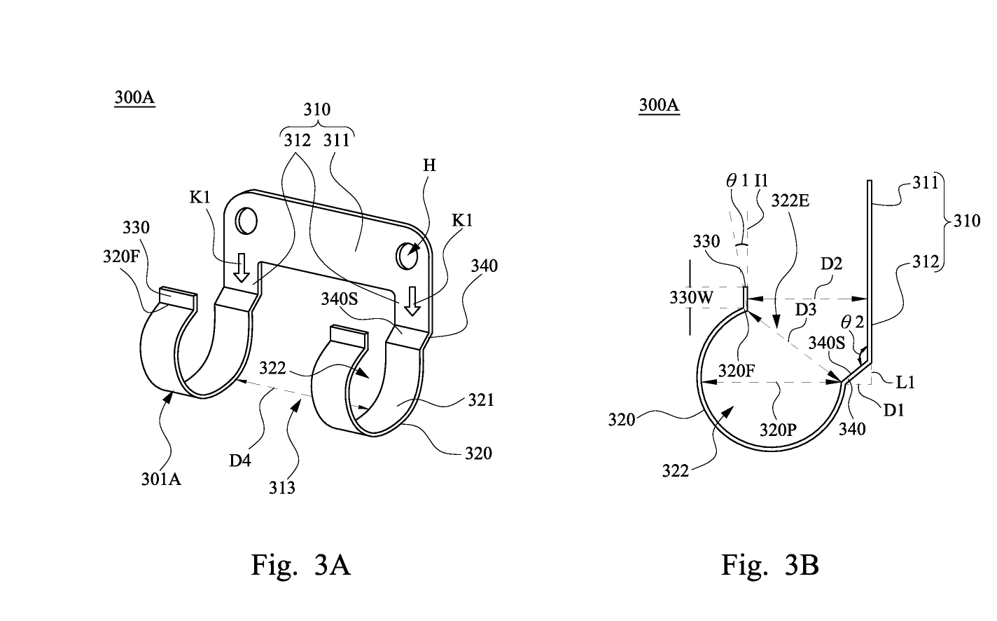

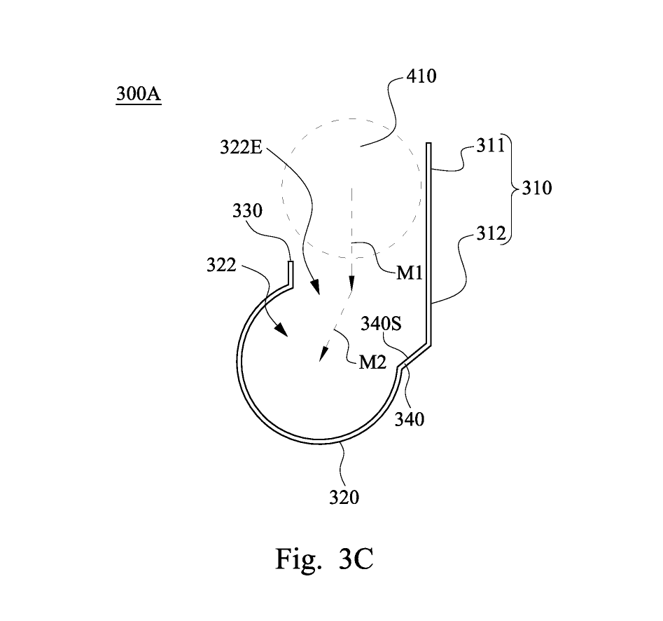

FIG. 3A is a perspective view of a bracket shown in FIG. 2A. As shown in FIGS. 2A and 3A, in the first embodiment, two hanging portions 301A (such as a pair of hanging portions) are disposed on the bracket 300A and spaced at a distance. When the T-shaped electrical junction 400 in FIG. 2A is disposed on the two hanging portions 301A, the horizontal portion 410 of the T-shaped electrical junction 400 is disposed on the two hanging portions 301A, and the vertical portion 460 of the T-shaped electrical junction 400 passes through the space between the two hanging portions 301A. Meanwhile, only the horizontal portion 410 of the T-shaped electrical junction 400 is supported by the hanging portions 301A. However, the present invention is not limited thereto, the number of the hanging portion may be several pairs.

Specifically, as shown in the FIG. 3A, the connecting portion 310 of the bracket 300A is U-shaped or approximately U-shaped, including a slab 311 and two extending ribs 312. The slab 311 has screw holes H for fixing the slab 311 on the frame 200 (as shown in FIG. 2A). The slab 311 is coplanar with the two extending ribs 312, and the two extending ribs 312 are integrally formed and extend from two opposite ends of a longer side of the slab 311 along the same extending direction K1, and the two extending ribs 312 are respectively connected to the two hanging portions 301A. Because the hanging portions 301A are respectively disposed at the same side of the connecting portion 310, there is a gap 313 between the hanging portions 301A, such that the vertical portion 460 of the T-shaped electrical portion 400 can pass through the gap 313 (as shown in FIG. 2A).

For example, each of the hanging portions 301A includes a C-shaped hook 320 with a C-shaped or an approximately C-shaped cross section of which an inner surface in a C-shaped cambered surface 321 which defines a holding space 322. The first section 420 and the second section 430 of the horizontal portion 410 are at least partially inserted into the holding space 322 of the C-shaped hooks 320, and are supported by the C-shaped hooks 320.

For enabling the horizontal portion 410 to be disposed in the holding space 322 more stably, as shown in FIG. 2B, the first section 420 and the second section 430 of the horizontal portion 410 respectively include coaxial rods 440 and flanges 441. The flanges 441, such as in ring shapes or approximate ring shapes, are located between the middle section 450 and the rods 440. A width 450W of the middle section 450 is greater than an outer diameter 441P of the flange 441. An outer diameter 441P (such as 29.6 mm) of the flange 411 is greater than an outer diameter 440P of the rod 440. However, the present invention is not limited thereto, the flanges may be omitted on the first section and the second section of the horizontal portion.

As shown in FIG. 2A, when the first section 420 and the second section 430 of the horizontal portion 410 are being respectively disposed in the holding space 322 of the two C-shaped hooks 320, the flange 441 of the first section 420 and the flange 441 of the second section 430 of the horizontal portion 410 are mated to contact the C-shaped cambered surface 321, such that the horizontal portion 410 is closely disposed on the C-shaped hooks 320. However, the present invention is not limited thereto, the flanges of the horizontal portion may be changed to other geometrical shapes (such as square or hexagon), and each of the C-shaped hooks of the hanging portion also may be changed to a shape matching the horizontal portion.

As shown in FIG. 3A, for assisting the assembler to smoothly dispose the horizontal portion 410 in the two holding spaces 322, the bracket 300A further includes a pair of first guide ribs 330 and a pair of second guide ribs 340. The pair of guide ribs 330 are respectively connected to free ends 320F of the two C-shaped hooks 320, and are extended along an extending direction parallel to the extending direction K1 (referring to a hypothetical extending line l1 shown in FIG. 3B), i.e., the guide ribs 330 are disposed parallel to the connecting portion 310, thereby guiding the horizontal portion 410 to move towards an entrance 322E of the holding space 322. One having the ordinary skill in the art may adjust the width 330W of the first guide ribs 330 extending along the hypothetical line l1 in accordance with actual requirements. For example, but the present invention is not limited thereto, the width 330W of the guide ribs 330 may be in a range from 4 mm to 6 mm, or in other ranges.

In other embodiments, referring to FIG. 3B, besides extending along the hypothetical extending line l1, each of the first guide ribs 330 also may be obliquely disposed at the free ends 320F of the C-shaped hooks 320, meaning that a first included angle θ1 is formed between each of first guide ribs 330 and the hypothetical line l1. One having the ordinary skill in the art may adjust the first included angle θ1 in accordance with actual requirements. For example, but the present invention is not limited thereto, the first included angle 91 may be in a range from 5° to 20°, or in other ranges. Therefore, by the respective first guide ribs 330, the horizontal portion 410 may more accurately slide into the entrance 322E of the holding space 322.

Each of the second guide ribs 340 is obliquely connected between the connecting portion 310 and the C-shaped hooks 320, and a second included angle θ2 is formed between each of the second guide ribs 340 and the connecting portion 310. Besides, each of the second guide ribs 340 has a slant face 340S used for guiding the horizontal portion 410 to enter the holding space 322. One having the ordinary skill in the art may adjust the second included angle θ2 in accordance with actual requirements. For example, but the present invention is not limited thereto, the second included angle θ2 may be an obtuse angle and in a range from 115° to 155°, or in other angle ranges.

Besides, because each of the second guide ribs 340 is obliquely connected between the connecting portion 310 and the C-shaped hooks 320, the C-shaped hooks 320 are located laterally away from a plane on which the connecting portion 310 is disposed. Therefore, the horizontal portion 410 does not interfere with the frame 200 (as shown in FIG. 2A) when the horizontal portion 410 is placed into the C-shaped hooks 320. The C-shaped hook 320 is located laterally away from the connecting portion 310 at a horizontal distance, i.e. a first minimum straight line distance D1 from a joint of the second guide ribs 340 and the C-shaped hooks 320 horizontal extending to a hypothetical extending line L1 of the connecting portion 310. For example, but the present invention is not limited thereto, the first minimum straight line distance D1 may be in a range from 4 mm to 7 mm or in other ranges. However, One having the ordinary skill in the art may adjust the first minimum straight line distance D1 in accordance with actual requirements.

FIG. 3C illustrates movement paths of the horizontal portion 410 entering the holding space 322 of the C-shaped hook 320. As shown in FIG. 3C, when the horizontal portion 410 is going to be disposed in the C-shaped hook 320, the horizontal portion 410 is first guided by the first guide rib 330 and the extended rib 312 to moved towards the entrance 322E (referring to a first movement direction M1), and then, the horizontal portion 410 is guided by the second guide rib 340 to enter the holding space 322 from the entrance 322E (referring to a second movement direction M2). Alternatively, the horizontal 410 also may be removed from the holding space 322 of the C-shaped hook 320 reversely along the second movement direction M2 and the first movement direction M1.

FIG. 3B is a side view showing the bracket 300A in FIG. 3A. As shown in FIG. 3B, for making the horizontal portion 410 not escaping from the C-shaped hook 320 easily after being disposed in the holding space 322 (as shown in FIG. 2A), an inner diameter 320P of the C-shaped hook 320 may be designed to be equal to the outer diameter 441P of the flange 441 of the horizontal portion 410. For example, but the present invention is not limited thereto, the inner diameter 320P of the C-shaped hook 320 may be in a range from 31 mm to 32 mm, or in other ranges. However, one having the ordinary skill in the art may design the inner diameter 320P of C-shaped hook 320 to be greater than or equal to the outer diameter 441P of the flanges 441 of the horizontal portion 410 in accordance with actual requirements.

For further making the horizontal portion 410 not escaping from the C-shaped hook 320 easily after being disposed in the holding space 322 (as shown in FIG. 2A), as shown in FIG. 3B, a second minimum straight line distance D2 between each of the first guide ribs 330 and the connecting portion 310 may be smaller than or equal to the outer diameter 441P of the flange 441 of the horizontal portion 410, such that the horizontal portion will not escape from the bracket 300A easily. For example, but the present invention is not limited thereto, the second minimum straight line distance D2 may be in a range from 25.7 mm to 27.5 mm, or in other ranges. However, the present invention in not limited thereto, and one having the ordinary skill in the art may adjust the second minimum distance D2 to be greater than or equal to the outer diameter 441P of the flange 411 of the horizontal portion 410 in accordance with actual requirements.

As shown in FIG. 3B, the entrance 322E of each of the holding space 322 is located between the first guide ribs 330 and the second guide ribs 340, and there is a third minimum straight line distance D3 between the first guide rib 330 and the second guide rib 340, i.e. the width of the entrance 322E. The third straight line distance D3 may be smaller than or equal to the outer diameter 441P of the flange 441 of the horizontal portion 410 (as shown in FIG. 2B), thereby restricting the first section 420 and the second section 430 of the horizontal portion 410 in the holding space 322, such that the horizontal portion 410 of the T-shaped junction 400 will not escape from the C-shaped hook 320 easily. For example, but the present invention is not limited thereto, the third straight line distance D3 may be in a range from 26 mm to 27.5 mm, or in other ranges. However, the present invention is not limited thereto, one having the ordinary skill in the art may adjust the third minimum distance D3 to be greater than or equal to the outer diameter 441P of the flange 411 of the horizontal portion 410 in accordance with actual requirements.

However, because the bracket 300A is made of such as metal or plastic, but the present invention is not limited thereto, the bracket 300A is elastic, such that the first section 420 and the second section 430 of the horizontal portion 410 can be pushed into the holding space 322 from a space between the first guide ribs 330 and the connect portion 310 or between the first guide ribs 330 and the second guide ribs 340 (entrance 322E).

As shown in FIG. 3A, one having the ordinary skill in the art may adjust a fourth minimum straight line distance D4 between two the C-shaped hooks to be greater than an outer diameter 460P of the vertical portion 460 in accordance with actual requirements (as shown in FIG. 2B). For example, but the present invention is not limited thereto, the fourth minimum straight line distance D4 may be in a range from 60.2 mm to 61 mm, or in other ranges.

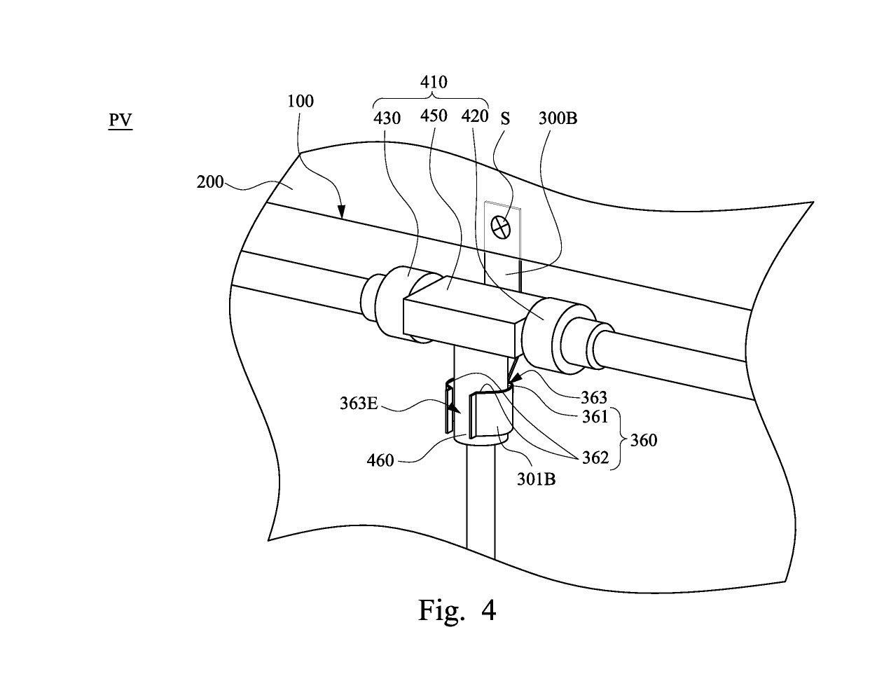

FIG. 4 is a partial perspective view of a photovoltaic apparatus PV according to a second embodiment, and the location of the detail portion shown in FIG. 4 is the same as detail portion 2A shown in FIG. 1B. As shown in FIG. 4, the photovoltaic apparatus PV in the second embodiment is substantially the same as the photovoltaic apparatus PV in FIG. 1B except that the bracket 300B in the second embodiment has only one hanging portion 301B and the hanging portion 301B in the second embodiment is a clamping element 360 for fastening and supporting the vertical portion 460 of the T-shaped electrical junction 400.

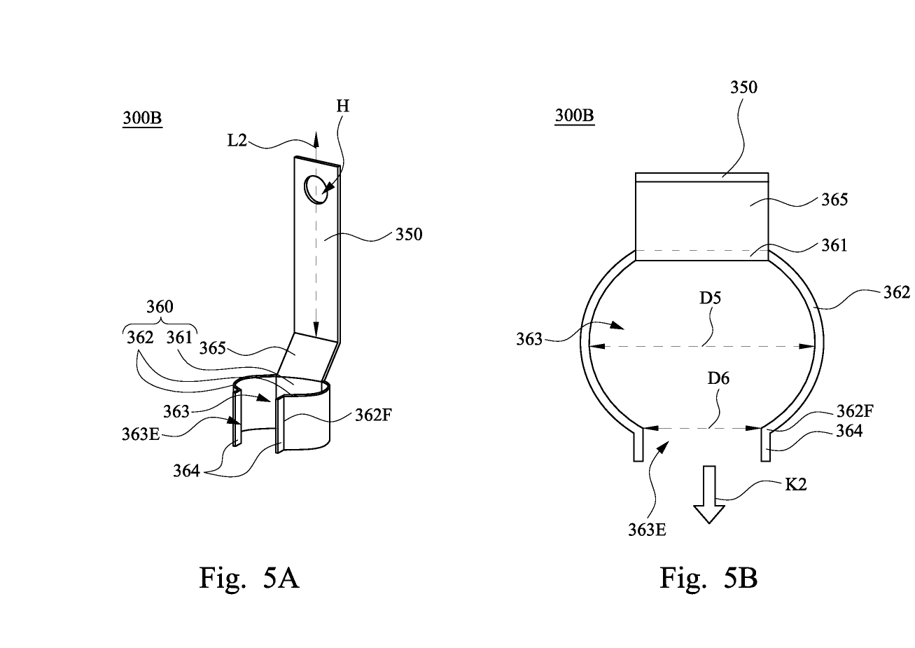

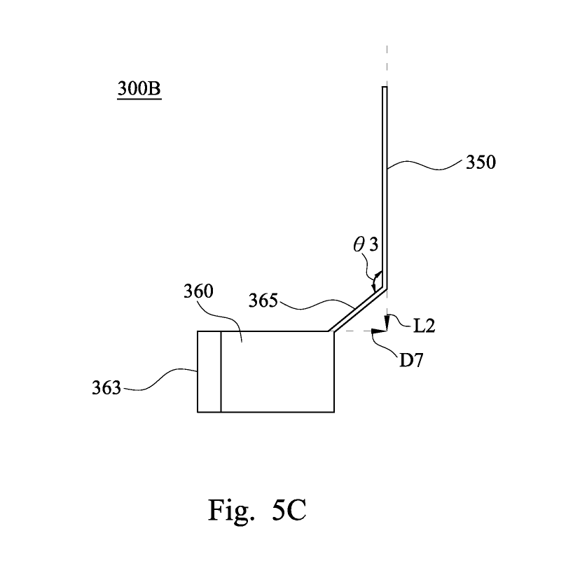

FIG. 5A is a perspective view of the bracket 300B shown in FIG. 4. FIG. 5B is a top view of the bracket 300B shown in FIG. 5A. As shown in FIGS. 5A and 5B, specifically, the bracket 300B includes a connecting portion 350. The connecting portion 350 is a slab extending along its longer axis with two opposite ends, and one of the two opposite ends has a screw hole H for fixing the connecting portion 350 on the frame 200 (as shown in FIG. 4), and the other of the two opposite ends is connected to the clamping element 360. The clamping element 360 includes a body 361 and two (a pair of) arc elastic arms 362. The body 361 is connected to the other of the two opposite ends of the connecting portion 350. For example, the arc elastic arms 362 are C-shaped or approximately C-shaped, and ends of the two arc elastic arms 362 are respectively connected to two opposite sides of the body 361, such that the two arc elastic arms 362 together with the body 361 define the accommodating space 363. The two arc elastic arms 362 together clamp the vertical portion 460 of the T-shaped electric junction 400 for allowing the vertical portion 460 of the T-shaped electric junction 400 to be partially disposed in the accommodating space 363 and supported by clamping element 360. The other ends of the two arc elastic arms 362 are two free ends 362F which are separated to form an entrance 363E. Because the entrance 363E of the clamping element 360 faces the body 361, the vertical portion 460 may move towards the body 361 to enter the accommodating space 363 through the entrance 363E. However, the present invention is not limited thereto. The clamping element 360 also may be one single C-shaped fastener, and the number of the arc elastic arms 362 also may be plural pairs.

A diameter of the accommodating space 363, such as a maximum straight-line distance D5 between the arc elastic arms 362, is smaller than or substantially equal to the outer diameter 460P (as shown in FIG. 2B) of the vertical portion 460. For example, but the present invention is not limited thereto, the maximum straight-line distance D5 is in a range from 27 mm to 33 mm, or in other ranges.

The width of the entrance 363E of the clamping element 360 can be adjusted, such that a minimum straight line distance D6 between two free ends 362F is smaller than the outer diameter 460P (as shown in FIG. 2B) of the vertical portion 460 such that the vertical portion 460 does not escape from the clamping element 360 through the entrance 363E easily. However, because the bracket 300B is made of such as metal or plastic (but the present invention is not limited thereto), the bracket 300B is elastic. Thus, the vertical portion 460 may still push open the two arc elastic arms 362 from the entrance 363E when entering the accommodating space 363. The minimum straight-line distance D6, for example, but the present invention is not limited thereto, is in a range from 22 mm to 26 mm, or in other ranges.

For assisting the assembler to smoothly dispose the vertical portion 460 in the accommodating space 363 (as show in FIG. 4), as shown in FIGS. 5A and 5B, the bracket 300B further includes at least one pair of guide ribs 364, which are respectively connected to the free ends 362F of the arc elastic arms 362, and extend from the body 361 along a direction K2 (as shown in FIG. 5B). Therefore, when the vertical portion 460 of the T-shaped electrical junction shown in FIG. 4 is about to enter the accommodating space 363, the guide ribs 364 may guide the vertical portion of the T-shaped electrical junction 400 to enter the accommodating space 363 from the entrance 363E of the clamping element 360 more accurately.

Furthermore, FIG. 5C is a side view of the bracket 300B in FIG. 5A. Referring to FIGS. 5B and 5C, the bracket 300B further includes a transverse rib 365. The transverse rib 365 is obliquely connected between the body 361 and the connecting portion 350, and an included angle θ3 is formed between the transverse rib 365 and the connecting portion 350. One having the ordinary skill in the art of the present invention may adjust the included angle θ3 in accordance with actual applications. For example, but the present invention is not limited thereto, the included angle θ3 may be an obtuse angle which is in a range from 115 degrees to 155 degrees, or in other ranges. Referring to FIG. 5C, because the transverse rib 365 is obliquely connected between the body 361 and the connecting portion 350 (as shown in FIG. 5A), the clamping element 360 is located laterally away from the connecting portion 350 so that the clamping element 360 is not located on the hypothetical extending line L2 of the longer axis direction of the connecting portion 350. Thus, the horizontal portion 410 of the T-shaped electrical junction will not be blocked by the connecting portion 350 (as shown in FIG. 4) when the vertical portion 460 enters the accommodating space 363. The clamping element 360 is located laterally away from the connecting portion 350 at a horizontal distance, i.e. a minimum straight line distance D7 from the joint of the transverse 365 and the body 361 horizontally extending to the hypothetical extending line L2 of connecting portion 350. For example, the minimum straight-line distance D7 is in a range from 4 mm to 7 mm or in other ranges. However, one having the ordinary skill in the art may adjust the minimum straight-line distance D7 in accordance with actual applications.

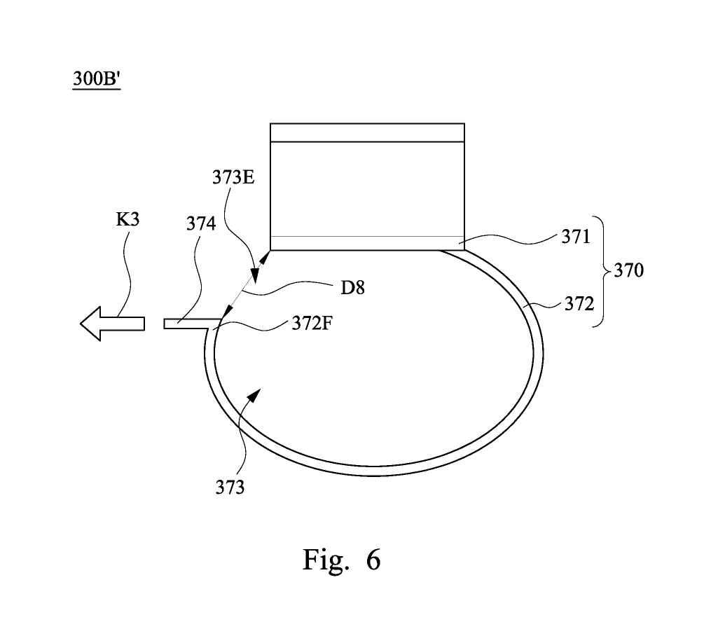

However, one having the ordinary skill in the art may flexibly change the position of the clamping element in accordance with actual applications. For example, FIG. 6 is a top view of another bracket 300B′ according to the second embodiment. As shown in FIG. 6, the clamping element 370 includes a body 371 and a single arc elastic arm 372. The body 371 defines two opposite sides. The arc elastic arm 372 is, for example, C-shaped or approximately C-shaped with two opposite ends, and one end of the arc elastic arm 372 is connected to one side of the body 371 and defines an accommodating space 373 with the body 371, and an entrance 373E is formed between the other end of the arc elastic arm 372 and the other side of the body 371. Because the entrance 373E of the clamping element 370 is located between the arc elastic arm 372 and the body 371, the vertical portion 460 may enter the accommodating space 373 therefrom. The arc elastic arm 372 is used for fastening and supporting the vertical portion 460 (as shown in FIG. 6).

The entrance 373E of the accommodating space 373 is located between the arc elastic arm 372 and the body 371, and has a minimum straight-line distance D8. One having the ordinary skill in the art may adjust the minimum straight-line distance D8 to be smaller than the outer diameter 460P of the vertical portion 460, such that the vertical portion 460 will not escape from the clamping element 370 easily. However, because the clamping element 370 is made of such as metal or plastic (but the present invention is not limited thereto), the clamping element 370 is elastic. Therefore, when the vertical portion 460 enter the accommodating space 373, the vertical portion 460 may still push open the arc elastic arm 372 for allowing the vertical portion 460 to enter the accommodating space 373 from the entrance 373E of the clamping element 370.

For assisting the assembler to dispose the vertical portion 460 in the accommodating space 373, the free end 372F of the arc elastic arm 372 includes a guide rib 374 extending away the accommodating space 373 along a direction K3. Therefore, the guide rib 374 may guide the vertical portion 460 to enter the accommodating space 373 from the entrance 373E more accurately.

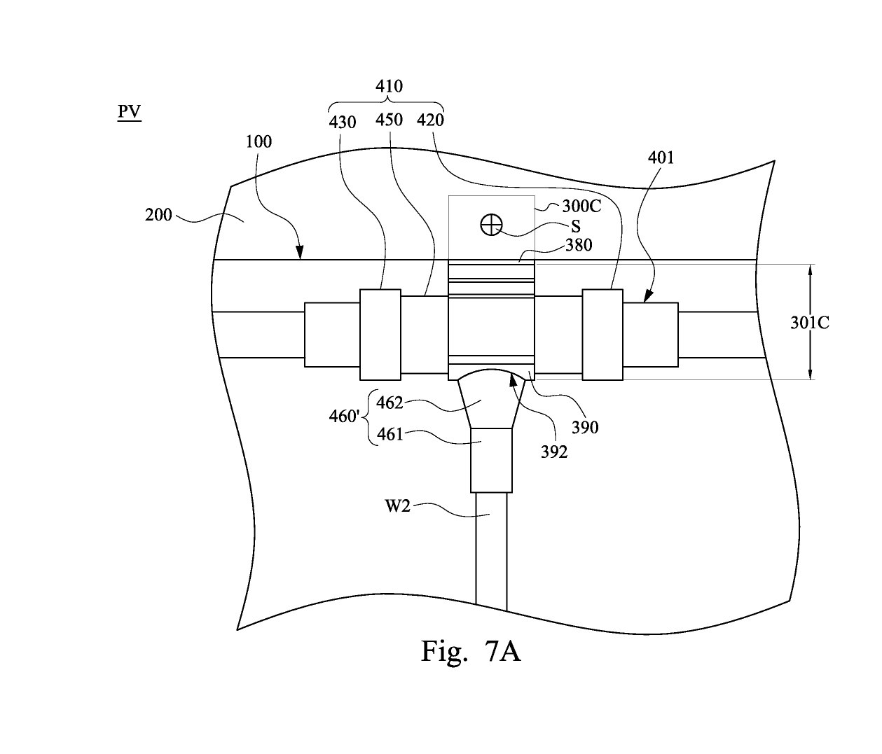

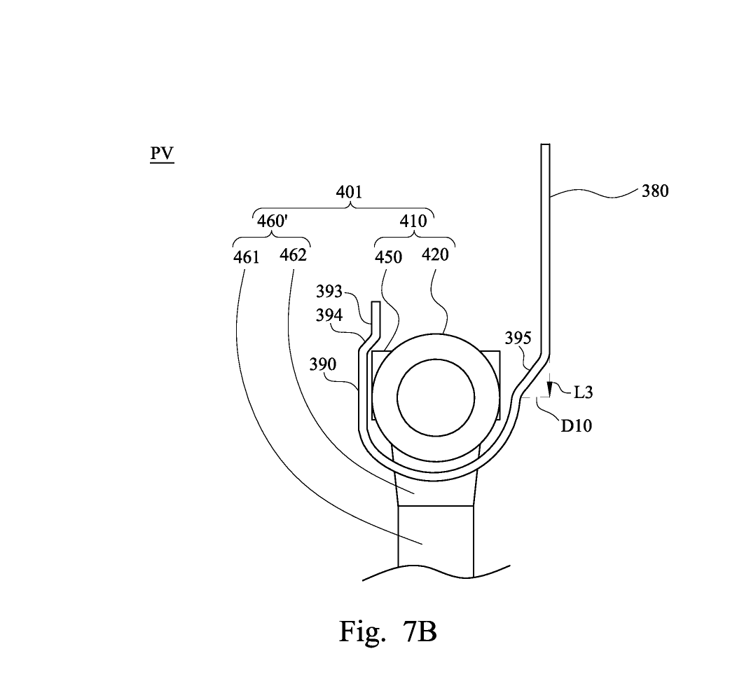

FIG. 7A is a partial perspective view of a photovoltaic apparatus according to a third embodiment and the detail portion of FIG. 7A is the same as the detail portion 2A shown in FIG. 1B. FIG. 7B is a side view of a bracket and a T-shaped electrical junction shown in FIG. 7A. As shown in FIGS. 7A and 7B, the photovoltaic PV of the third embodiment is substantially the same as the photovoltaic PV in FIG. 1B, and their differences are that, in the third embodiment, there is only one single hanging portion, and the hanging portion is a position-limiting hook 390 which receives the horizontal portion 410 (such as middle section 450) therein, and the vertical portion 460′ is restricted and supported by the position-limiting hook 390. Furthermore, the vertical portion 460′ of the T-shaped electrical junction 401 of the third embodiment has a cylinder 461 and a coaxial cone-shaped portion 462, and the cone-shaped portion 462 is connected between the cylinder 461 and the middle section 450, and the cylinder 461 is connected to the wire W2. The cross-section area of the cone-shaped portion 462 is decreased along a direction from the middle section 450 towards the cylinder 461. However, the vertical portion of the T-shaped electrical junction of the first embodiment and the second embodiment may also have cylinder and cone structures.

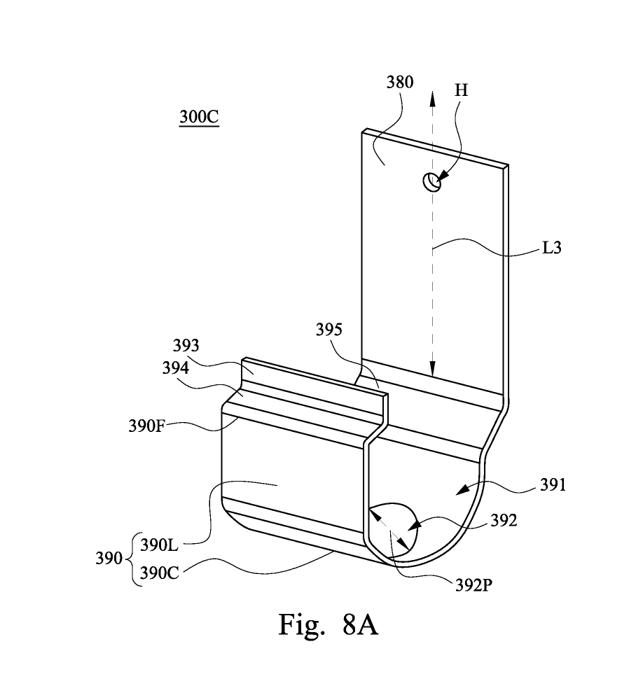

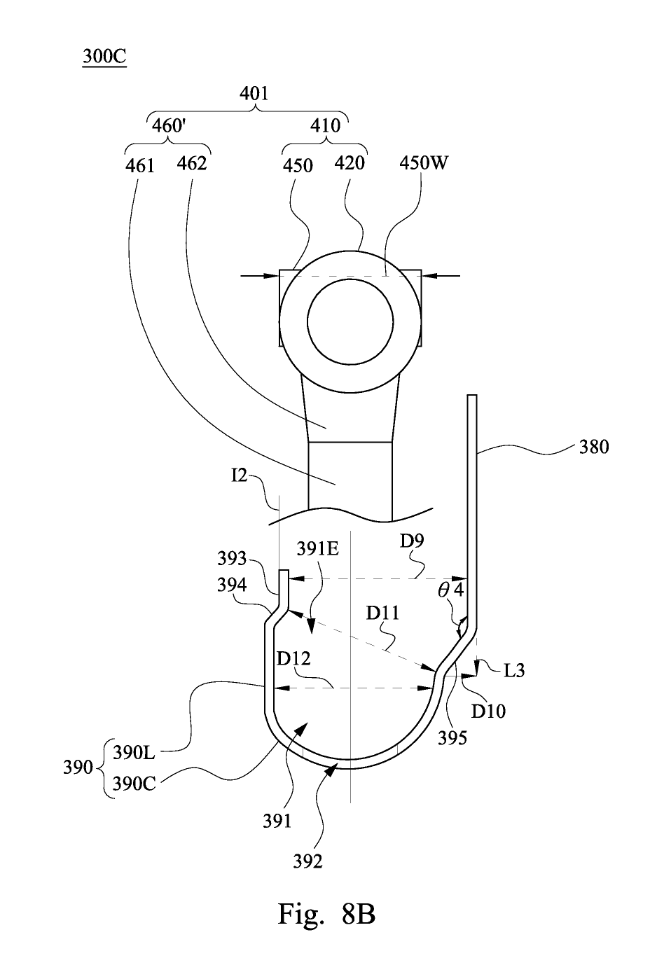

FIG. 8A is a perspective view of the bracket shown in FIG. 7A. FIG. 8B is a side view of the bracket shown in FIG. 8A. Specifically, as shown in FIG. 8A, the bracket 300C includes a connecting portion 380. The connecting portion 380 is a slab extending along its longer axis, and has two opposite ends, in which one end has a screw hole H for fixing the connecting portion 380 on the frame 200 (as shown in FIG. 7A), and the other end is connected to the position-limiting hook 390.

For example, the position-limiting hook 390 is C-shaped or approximately C-shaped, and the position-limiting hook 390 has an accommodating groove 391, and the position-limiting hook 390 has at least one through hole 392 in the accommodating groove 391. For example, a hole diameter 392P of the through hole 392 is in a range from 27 mm to 33 mm or in other ranges. Further specifically, the position-limiting hook 390 includes an arc section 390C and a linear section 390L, and the arc section 390C is connected between the linear section 390L and the connecting portion 380. The linear section 390L extends along the hypothetical extending line l2, and is parallel to the hypothetical extending line L3 of the longer axis of the connecting portion 380 (as shown in FIG. 8B). The through hole 392 is disposed on the arc section 390C.

As shown in FIG. 8B, when the T-shaped electrical junction 401 is going to be placed into the accommodating groove 391, the cylinder 461 of the vertical portion 460′ has first to pass through the through hole 392 of the arc section 390C, and then, the cone-shaped portion 462 of the vertical portion 460′ is restricted (i.e. clamped) in the through hole 392, thereby limiting the downward, rightward and leftward movements of the T-shaped electrical junction 401, and thus at least one portion of the horizontal portion 410 of the T-shaped electrical junction 401 is disposed in the accommodating groove 391.

Furthermore, in other embodiments, the cylinder 461 may be connected to the wire W2 pluggably via socket (not shown). Therefore, when the vertical portion 460′ is desired to enter the through hole 392, the wire W2 does not need to be stretched out of the through hole 392 entirely from the accommodating groove 391, thereby conveniently hanging the T-shaped electrical junction 401 (FIG. 7A).

For making the horizontal portion 410 (such as the middle section 450, FIG. 7A) of the T-shaped electrical junction 401 firmly disposed in the accommodating groove 391, as shown in the FIG. 8A, the bracket 300C further includes at least one position-limiting portion 394. The position-limiting portion 374 is a slab connected to the free ends 390F of the position-limiting hook 390 and obliquely extends towards the connecting portion 380.

As shown in FIG. 8B, because the bracket 300C is elastic, when the horizontal portion 410 is going to enter the accommodating groove 391, the horizontal portion 410 can press and deform the position-limiting portion 390. The horizontal portion 410 is pushed into the accommodating groove 391 after the position-limiting 390 is deformed, and then the position-limiting hook 390 (as shown in FIG. 7B) returns to its original position, the position-limiting portion 394 is fastened on the middle section 450 promptly, thereby restricting the horizontal portion 410 in the accommodating groove 391 to limit the upward movement of the T-shaped electrical junction 401.

For assisting the assembler to accurately insert the vertical portion 460′ through the through hole 392 of the accommodating groove 391, the bracket 300C further includes at least one guide rib 393. The guide rib 393 is connected to one side of the position-limiting portion 394 opposite to the side connecting the position-limiting hook 390 and upwardly extends along the hypothetical extending line l2, which is parallel to the long axis of the connecting portion 380 (referring to the hypothetical extending line L3).

Therefore, when the T-shaped electrical junction 401 of FIG. 8B is placed into the position-limiting hook 390, the guide rib 393 and the connecting portion 380 guides the vertical portion 460′ of the T-shaped electrical portion 401 to enter the accommodating groove 391 smoothly.

Further, as shown in FIG. 8B, a minimum straight line distance D9 between the guide rib 393 and the connecting portion 380 may be smaller than or equal to the width 450W of the middle section 450, such that the horizontal portion 410 will not escape from the bracket 300C easily. For example, but the present invention is not limited thereto, the minimum straight-line distance D9 is in a range from 33 mm to 36 mm or in other ranges. However, the present invention is not limited thereto, one having the ordinary skill in the art may adjust the minimum straight line distance D9 to be greater than the width 450W of the middle section 450 in accordance with actual requirements.

Furthermore, the bracket 300C further includes the transverse rib 395. The transverse rib 395 is obliquely connected between the position-limiting hook 390 and the connecting portion 380 and an included angle θ4 is includes between the connecting portion 380 and the transverse rib 395. The included angle θ4 is an obtuse angle in a range from 115 degrees to 155 degrees or in other angle ranges.

Because the transverse rib 395 is obliquely connected between the position-limiting hook 390 and the connecting portion 380, the position-limiting hook 390 is located laterally away from the connecting portion 380 so that the position-limiting hook 390 is not located on the hypothetical extending line L3 of the longer axis of the connecting portion 380, and further the horizontal portion 410 is not blocked by the connecting portion 380 during the vertical portion 460′ of the T-shaped electrical portion 401 is disposed into the through hole 392.

The horizontal distance from position-limiting hook 390 to the connecting portion 380 is equal to a minimum straight line distance D10, which is a gap between the joint of the transverse rib 395 and the position-limiting hook 390 and the hypothetical extending line L3 of the connecting portion 380. This distance is in a range from 4 mm to 7 mm or in other ranges. However, one having the ordinary skill in the art may adjust the minimum straight-line distance D10 in accordance with actual requirements.

The entrance 391E of the accommodating groove 391 is formed between the guide rib 393 and the transverse rib 395, and there is a minimum straight line distance D11 between the guide rib 393 and the transverse rib 395. The minimum straight-line distance D11 is smaller than the width 450W of the middle section 450 for restricting the middle section 450 in the accommodating groove 391, such that the horizontal portion 410 of the T-shaped electrical junction 401 will not escape from the position-limiting hook 390 easily. For example, but the present invention is not limited thereto, the minimum straight-line distance D11 is in a range from 31 mm to 34 mm or in other ranges. However, because the bracket 300C is made of such as metal or plastic, but the present invention is not limited thereto, the bracket 300C is elastic, such that the middle section 450 of the horizontal portion 410 still be pushed into the accommodating groove 391 through the gap between the guide rib 393 and the connecting portion 380, as well as the gap between the guide rib 393 and the transverse rib 395 (i.e. entrance 391E).

However, the present invention is not limited thereto, one having the ordinary skill in the art may adjust the minimum straight line distance D11 to be greater than the width 450W of the middle section 450 of the horizontal portion 410.

There is a minimum straight-line distance D12 from the linear section 390L to the joint of the transverse rib 395 and the arc section 390C. The minimum straight-line distance D12 is smaller than or substantially equal to the width 450W of the middle section 450. For example, but the present invention is not limited thereto, the minimum straight-line distance D12 is in a range from 31 mm to 33 mm, or in other ranges.

Furthermore, referring to FIG. 1B, the photovoltaic apparatus PV further includes a junction box 500 and a micro inverter 600. The junction box 500 and the micro inverter 600 are both fixed on the back surface 100B of the photovoltaic panel 100. The junction box 500 is electrically connected to the photovoltaic panel 100 of the photovoltaic apparatus PV and the micro inverter 600 for transmitting direct current (DC) generated by the photovoltaic panel 100 to the micro inverter 600. The micro inverter 600 is electrically connected to the junction box 500 via several wires W1 (such as two). The micro inverter 600 is electrically connected to the connection C3 and is electrically connected to the T-shaped junction 400 via the wire W2 for transmitting alternating current (AC) transformed from the DC to T-shaped junction 400.

Finally, the embodiments in the foregoing is not used for limiting the present invention, various modifications and variations may be made to the structure of the present invention are protected in the present invention by those skilled in this art without departing from the scope or spirit of the invention. Therefore, the scope of patent protection of the present invention is based on the scope of the attached patents.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A photovoltaic apparatus, comprising:
a frame having a accommodating space;
a photovoltaic panel disposed in the accommodating space;
a T-shaped electrical junction for electrically connecting the photovoltaic panel to two external devices; and
a bracket comprising a connection portion and at least one hanging portion, wherein the connection portion is in a slab shape for fixing the bracket on the frame, and the at least one hanging portion is used for supporting the T-shaped electrical junction.

2. The photovoltaic apparatus of claim 1, wherein the T-shaped electrical junction comprises:
a horizontal portion, comprising:
a first section electrically connected to one of the external devices;
a second section electrically connected to the other of the external devices; and
a middle section disposed between the first section and the second section; and
a vertical portion connected to the middle section of the horizontal portion, and electrically connected to the photovoltaic panel,
wherein at least one of the horizontal portion and the vertical portion is supported by the at least one hanging portion.

3. The photovoltaic apparatus of claim 2, wherein the number of the at least one hanging portion is a pair for respectively supporting the first section and the second section of the horizontal portion of the T-shaped electrical junction, and allowing the vertical portion of the T-shaped electrical junction to pass through a gap between the hanging portions.

4. The photovoltaic apparatus of claim 3, wherein each of the hanging portions comprises a C-shaped hook defining a holding space, for respectively receiving at least one portion of the first section and at least one portion of the second section of the horizontal portion of the T-shaped electrical junction therein.

5. The photovoltaic apparatus of claim 4, wherein the bracket further comprises:
at least one pair of first guide ribs respectively connected to a free end of the C-shaped hooks; and
at least one pair of second guide ribs respectively obliquely connected between the connecting portion and the C-shaped hooks, and an included angle formed between the connecting portion and each of the second guide ribs is an obtuse angle.

6. The photovoltaic apparatus of claim 2, wherein the hanging portion comprises:
a body connected to the connecting portion; and
at least one arc elastic arm, wherein an accommodating space is mutually defined by the body and the at least one arc elastic arm for receiving at least one portion of the vertical portion of the T-shaped electrical junction therein.

7. The photovoltaic apparatus of claim 6, wherein the bracket further comprises:
a transverse rib obliquely connected between the body and the connecting portion, and an included angle formed between the transverse rib and the connecting portion is an obtuse angle.

8. The photovoltaic apparatus of claim 6, wherein the at least one arc elastic arm is a pair of arc elastic arms respectively connected to two opposite sides of the body, and each of the arc elastic arms is defined with a free end, and a minimum distance between the free ends of the arc elastic arms is smaller than an outer diameter of the vertical portion of the T-shaped electrical junction.

9. The photovoltaic apparatus of claim 8, wherein the bracket further comprises:
at least one pair of guide ribs respectively connected to the free ends of the arc elastic arms and extending in a direction away from the body.

10. The photovoltaic apparatus of claim 6, wherein the body is defined with two opposite sides, and the arc elastic arm is connected to one side of the body, and a minimum distance between a free end of the arc elastic arm and the other side of the body is smaller than an outer diameter of the vertical portion of the T-shaped electrical junction.

11. The photovoltaic apparatus of claim 10, wherein bracket further comprises:
a guide rib disposed on the free end of the arc elastic arm.

12. The photovoltaic apparatus of claim 2, wherein the hanging portion comprises a position-limiting hook connected to the connecting portion, a accommodating groove is defined in the position-limiting hook for receiving at least one portion of the horizontal portion of the T-shaped electrical junction, and the position-limiting hook has at least one through hole for allowing the vertical portion of the T-shaped electrical junction to pass through.

13. The photovoltaic apparatus of claim 12, wherein the bracket further comprises:
a position-limiting portion disposed on a free end of the position-limiting hook and obliquely extending towards the connecting portion for restricting the horizontal portion of the T-shaped electrical junction in the accommodating groove.

14. The photovoltaic apparatus of claim 13, wherein the bracket further comprises:
at least one guide rib connected to a side of the position-limiting portion opposite to the position-limiting hook.

15. The photovoltaic apparatus of claim 12, wherein the bracket further comprises:
a transverse rib obliquely connected between the position-limiting hook and the connecting portion, and an angle included between the transverse rib and the connecting portion is an obtuse angle.

16. A bracket for supporting a T-shaped electrical junction of a photovoltaic apparatus, wherein the T-shaped electrical junction includes a horizontal portion and a vertical portion connected to each other, the bracket comprising:
a connecting portion in a slab shape for fixing the bracket on a frame of the photovoltaic apparatus; and
at least one pair of hanging portions connected to the connecting portions for supporting the horizontal portion of the T-shaped electrical portion, wherein a gap exists between the hanging portions for the vertical portion of the T-shaped electrical junction passing therethrough.

17. The bracket of claim 16, wherein each of the hanging portions comprises a C-shaped hook defining a holding space for receiving at least one portion of the horizontal portion of the T-shaped electrical junction.

18. The bracket of claim 17, further comprising:
at least one pair of first guide ribs respectively connected to a first free end of the C-shaped hook; and
at least one pair of second guide ribs respectively obliquely connected between the connecting portion and the C-shaped hook, and an included angle formed between the connecting portion and each of the second guide ribs is obtuse.

19. A bracket for supporting a T-shaped electrical junction of a photovoltaic apparatus, wherein the T-shaped electrical junction includes a horizontal portion and a vertical portion connected to each other, the bracket comprising:
a connecting portion in a slab shape for fixing the bracket on a frame of the photovoltaic apparatus; and
a single hanging portion connected to the connecting portion for supporting one of the vertical portion and the horizontal portion of the T-shaped electrical junction.

20. The bracket of claim 19, wherein the single hanging portion comprises:
a body connected to the connecting portion; and
at least one arc elastic arm together with the body to define a accommodating space for receiving at least one portion of the vertical portion of the T-shaped electrical junction therein and the at least one portion of the vertical portion of the T-shaped electrical junction supported by the at least one arc elastic arms.

21. The bracket of claim 20, wherein the number of the arc elastic arm is a pair, the arc elastic arms are respectively connected to two opposite sides of the body, each of the arc elastic arms has a free end, and a minimum distance between the free ends of the arc elastic arms is smaller than an outer diameter of the vertical portion of the T-shaped electrical junction.

22. The bracket of claim 20, wherein the bracket further comprises:
a transverse rib obliquely connected between the body of the single hanging portion and the connecting portion, and an included angle formed between the transverse rib and the connecting portion is an obtuse angle.

23. The bracket of claim 20, wherein the body has two opposite side, and one side of the body is connected to the arc elastic arm, and a minimum distance between a free end of the arc elastic arm and the other side of the body is smaller than an outer diameter of the vertical portion of the T-shaped electrical junction.

24. The bracket of claim 19, wherein the single hanging portion comprises:
a position-limiting hook connected to the connecting portion and defined with a accommodating groove for receiving and restricting the horizontal portion of the T-shaped electrical junction, wherein the position-limiting hook has a through hole for allowing the vertical portion of the T-shaped electrical junction to pass through.

25. The bracket of claim 24, further comprising:
a position-limiting portion which is disposed on a free end of the position-limiting hook, and obliquely extends towards the connecting portion for restricting the horizontal portion of the T-shaped electrical junction in the accommodating groove.

26. The bracket of claim 24, further comprising:
a transverse rib obliquely connected between the position-limiting hook and the connecting portion, and an included angle formed between the transverse rib and the connecting portion is an obtuse angle.
